(19) United States
(12) Patent Application Publication
(10) Pub. No.: US 2026/0269191 A1
(43) Pub. Date: Sep. 10, 2026

(54) SYSTEMS AND METHODS FOR CONTROLLING AN EDGE RING VOLTAGE WITH AN EXTERNAL RESONATOR AND AN OPTIONAL DIRECTDRIVETM

(71) Applicant: Lam Research Corporation, Fremont, CA (US)

(72) Inventors: Yuhou Wang, Fremont, CA (US); Alexander Miller Paterson, San Jose, CA (US); Michael John Martin, Fremont, CA (US); Tom A. Kamp, San Jose, CA (US); John S. Drewery, San Jose, CA (US)

(21) Appl. No.: 19/162,879

(22) PCT Filed: Mar. 1, 2024
(86) PCT No.: PCT/US2024/018249

§ 371 Date: Sep. 5, 2025

Related U.S. Application Data
(60) Provisional application No. 63/451,901, filed on Mar. 13, 2023.

(51) Int. Cl. H01J 37/32; H10P 72/00

(52) U.S. Cl. CPC H01J 37/32642; H01J 37/32146; H01J 37/3299; H10P 72/0421; H01J 2237/3343

(57) ABSTRACT

Systems and methods for controlling an edge ring voltage with an external resonator circuit and an optional DirectDrive™ are described. One of the systems includes the resonator coupled to an edge ring of a plasma chamber. The edge ring surrounds a substrate support of the plasma chamber. The system further includes a controller coupled to the resonator. The controller receives a first measurement signal from a bias sensor, receives a second measurement signal from a ring sensor, and controls based on the first and second measurement signals a parameter of the resonator to achieve uniformity in processing across a substrate.

### FIELD

The present embodiments relate to systems and methods for controlling an edge ring voltage with an external resonator and an optional DirectDrive™.

### BACKGROUND

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A plasma tool is used to process a substrate. A radio frequency (RF) generator of the plasma tool is connected to a match network of the plasma tool. The match network is connected to a chuck of a plasma chamber. The match network includes a network of capacitors and inductors. The substrate is placed on top of the chuck in the plasma chamber. One or more gases are supplied to the plasma chamber. Also, an RF signal is generated by the RF generator. The network of capacitors and inductors receives the RF signal and matches impedances between input and output of the match network to output another RF signal, and sends the other RF signal to the plasma chamber for processing the substrate. However, the substrate is not processed in a desirable way.

### SUMMARY

Embodiments of the disclosure provide systems, apparatus, methods and computer programs for controlling an edge ring voltage with a resonator and an optional DirectDrive™. It should be appreciated that the present embodiments can be implemented in numerous ways, e.g., a process, an apparatus, a system, a device, or a method on a computer readable medium. Several embodiments are described below.

In an embodiment, an edge ring voltage is controlled by changing an amount of coupling between an edge ring and a substrate support. The amount of coupling is changed by physically moving parts of the edge ring. However, it is difficult to move the parts of the edge ring when the edge ring is located inside a plasma chamber, such as a vacuum chamber, and is getting etched away gradually.

In one embodiment, an impedance matching network is used to modify power delivered to the edge ring from a 50-ohm radio frequency (RF) generator. The same impedance matching impacts the edge ring voltage, and this complicates a control loop for controlling the edge ring voltage. The edge ring voltage is also impacted by changing a coupling between the edge ring and the substrate support.

In one embodiment, an external resonator circuit to control the edge ring voltage, sometimes referred to herein as Vring, is provided. A main cathode, such as a substrate support, is powered by a bias RF source connected to it. As an example, the bias RF source is a combination of a 50-ohm RF generator, an impedance matching circuit, and a RF cable, or is a DirectDrive™ RF source, such as a matchless plasma source. A bias voltage, sometimes referred to herein as Vbias, is measured by a voltage sensor connected to the substrate support, to generate a measured voltage and the measured voltage is fed back to the bias RF source for control of the bias voltage. The edge ring is located in close proximity to the main cathode, and gets powered by the main cathode through capacitive coupling. A voltage on the edge ring is controlled via the external resonator circuit connected to the edge ring. When the external resonator circuit is used, there is no need to physically move the edge ring to modify an amplitude of the edge ring voltage. Also, when the external resonator circuit is used, the impedance matching network to modify the power delivered to the edge ring is not used, and this simplifies the control loop for controlling the edge ring voltage.

In an embodiment, a ring plasma load is typically a capacitively coupled plasma (CCP) and is characterized as a series combination of a capacitance of plasma at the edge ring and a resistance of plasma at the edge ring. The ring plasma load includes an additional parasitic capacitance along an RF delivery path. So, overall at a connection point of the external resonator circuit, the ring plasma load is a capacitive load. A function of the resonator circuit is to construct an inductive impedance, which is approximately in resonance with a capacitive impedance of the capacitive load or with the capacitance of plasma at the edge ring. When the resonance is achieved, the edge ring voltage is approximately equal to the bias voltage and uniformity in processing a substrate is achieved.

In one embodiment, a DirectDrive™ RF source, is added to provide additional power to a resonator circuit to gain further control over the edge ring voltage. A combination of the DirectDrive™ RF source and the resonator circuit is sometimes referred to herein as a drive-resonator circuit. In the embodiment, a variability of a capacitor of the resonator circuit is optional. The DirectDrive™ RF source has its output RF frequency set to be approximately the same or same as a frequency of the bias RF source, and a relative RF phase between an RF signal output from the DirectDrive™ RF and an RF signal output from the bias RF source is controlled.

In an embodiment, the resonator is set up such that the edge ring voltage is below a target level without power output from the DirectDrive™ RF source. From that as a starting point, RF power output from the DirectDrive™ RF source increases to increase the edge ring voltage with appropriate RF phase control. Also, a phase difference between Vring and Vbias is changed by changing a phase delay between RF signals output from the bias RF source and the DirectDrive™ RF source.

In one embodiment, the DirectDrive™ RF source takes power away from the resonator circuit. When a voltage at a direct current (DC) rail of the DirectDrive™ RF source is lower than a voltage at an output of the DirectDrive™ RF source, because the resonator circuit is powered from the bias RF source, the DC rail charges through a top transistor in a half-bridge circuit of the DirectDrive™ RF source when the top transistor turns on. This will result in a negative output power from the DirectDrive™ RF source.

In an embodiment, a system for controlling an edge ring voltage with a resonator is described. The system includes the resonator coupled to an edge ring of a plasma chamber. The edge ring surrounds a substrate support of the plasma chamber. The system further includes a controller coupled to the resonator. The controller receives a first measurement signal from a bias sensor, receives a second measurement signal from a ring sensor, and controls based on the first and second measurement signals a parameter of the resonator to achieve uniformity in processing across a substrate.

In an embodiment, a method for controlling an edge ring voltage with a resonator is described. The method includes receiving a first measurement signal from a bias sensor, receiving a second measurement signal from a ring sensor, and controlling based on the first and second measurement signals a parameter of the resonator to achieve uniformity in processing across a substrate. The resonator is coupled to an edge ring of a plasma chamber, and the edge ring surrounds a substrate support of the plasma chamber.

In one embodiment, a system for controlling an edge ring voltage with a resonator circuit is described. The system includes the resonator circuit coupled to an edge ring of a plasma chamber. The edge ring surrounds a substrate support of the plasma chamber. The system further includes a controller coupled to the resonator circuit. The controller receives a first measurement signal from a bias sensor, receives a second measurement signal from a ring sensor, and controls based on the first and second measurement signals a parameter of the resonator circuit to achieve uniformity in processing across a substrate

Some advantages of the herein described systems and methods include providing the resonator or the resonator circuit to achieve uniformity in processing the substrate. A voltage, such as a voltage amplitude, that is output from the resonator or the resonator circuit is controlled based on measurement signals associated with the edge ring and the substrate support to achieve uniformity. Also, in one case, a phase of the RF signal output from the DirectDrive™ RF source is modified to achieve a phase match between the measurement signals associated with the edge ring and the substrate support. By using the resonator circuit or a combination of the DirectDrive™ RF source and the resonator circuit, the uniformity is achieved.

Other aspects will become apparent from the following detailed description, taken in conjunction with the accompanying drawings.

### BRIEF DESCRIPTION OF THE DRAWINGS

The embodiments may best be understood by reference to the following description taken in conjunction with the accompanying drawings.

FIG. 1 is a diagram of an embodiment of a system to illustrate use of a resonator circuit.

FIG. 2 is a diagram of an embodiment of a system to illustrate details of the resonator circuit of FIG. 1.

FIG. 3A is an embodiment of a graph to illustrate a control of capacitance of a capacitor of the resonator circuit of FIG. 1 to achieve a percentage ratio between a voltage associated with an edge ring and a voltage associated with a substrate support.

FIG. 3B is an embodiment of a graph to illustrate a control of the capacitance of the capacitor of FIG. 3A to achieve a percentage ratio between the voltage associated with the edge ring and the voltage associated with the substrate support.

FIG. 4 is a diagram of an embodiment of a system to illustrate a resonator having a DirectDrive™, sometimes referred to herein as a matchless plasma source (MPS), and a resonator circuit.

FIG. 5A is a diagram of an embodiment of a system to illustrate details of a resonator circuit, which is an example of the resonator circuit of FIG. 4.

FIG. 5B is a diagram of an embodiment of a system to illustrate details of a resonator circuit, which is another example of the resonator circuit of FIG. 4.

FIG. 6 is a diagram of an embodiment of a system to illustrate details of an MPS, which is an example of the MPS of FIG. 4.

FIG. 7A is an embodiment of a graph to illustrate that a ratio of an amplitude of the voltage associated with the edge ring to an amplitude of the voltage associated with the substrate support is controlled by modifying an amplitude of a radio frequency (RF) signal output from the MPS of FIG. 4.

FIG. 7B is an embodiment of a graph to illustrate that a phase delay between a phase of the voltage associated with the edge ring and a phase of the voltage associated with the substrate support is controlled by modifying a phase delay between a phase of an RF signal generated by a bias source system and a phase of the RF signal output from the MPS of FIG. 4.

FIG. 7C is an embodiment of a graph to illustrate that RF power output from the MPS of FIG. 6 is a function of a phase delay between the phase of the RF signal generated by the bias source system and the phase of the RF signal output from the MPS of FIG. 4.

### DETAILED DESCRIPTION

The following embodiments describe systems and methods for controlling an edge ring voltage with an external resonator and an optional DirectDrive™. It will be apparent that the present embodiments may be practiced without some or all of these specific details. In other instances, well known process operations have not been described in detail in order not to unnecessarily obscure the present embodiments.

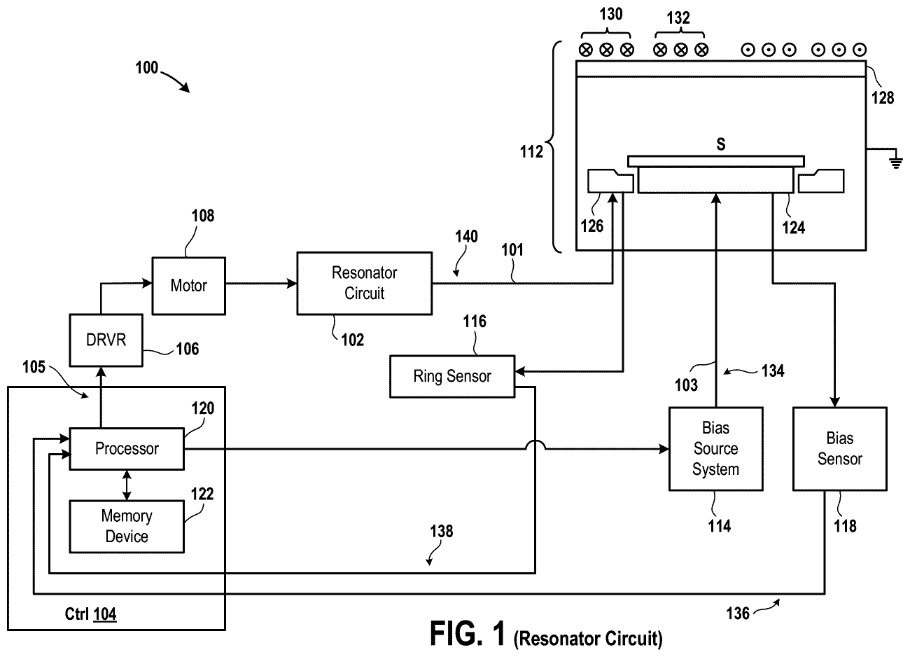

FIG. 1 is a diagram of an embodiment of a system 100 to illustrate use of a resonator circuit 102. The system 100 includes a controller 104, a driver 106, a motor 108, the resonator circuit 102, a plasma chamber 112, a bias source system 114, a ring sensor 116, and a bias sensor 118. As an example, the controller includes a processor 120 and a memory device 122, and the processor 120 is coupled to the memory device 122. Other examples of a controller include an application specific integrated circuit (ASIC), a programmable logic device (PLD), and a field programmable gate array (FPGA).

An example of a driver, as used herein, include one or more transistors that are coupled to each other. An example of each of the sensors 116 and 118 include a voltage sensor. To illustrate, the ring sensor 116 is a voltage sensor and the bias sensor 118 is another voltage sensor. An example of the motor 108 is an electric motor.

An example of the bias source system 114 is a combination of a bias radio frequency (RF) generator and a bias impedance matching circuit, and the bias radio frequency generator is coupled to the bias impedance matching circuit and the bias impedance matching circuit is coupled to an edge ring 126. Another example of the bias source system 114 is a bias matchless plasma source (MPS), such as a DirectDrive™, and a bias reactive circuit. The bias reactive circuit is coupled to the bias MPS and to a substrate support 124. An example of a matchless plasma source is provided below.

The plasma chamber 112 includes the substrate support 124, such as an electrostatic chuck (ESC), and the edge ring 126. The edge ring 126 is an annular ring that surrounds the substrate support 124. For example, the edge ring 126 is located adjacent to an outer periphery of the substrate support 124 to surround an edge of the substrate support 124. To illustrate, there is no other ring between the edge ring 126 and the substrate support 124. As another illustration, an inner diameter of the edge ring 126 is greater than an outer diameter of the substrate support 124. The plasma chamber 112 further includes a dielectric window 128, an RF coil 130 and another RF coil 132.

The processor 120 is coupled to the driver 106, which is coupled to the motor 108. The motor 108 is coupled to the resonator circuit 102, which is coupled to the edge electrode 126. For example, the resonator circuit 102 is coupled to the edge electrode 126 via an RF connection 101. Examples of an RF connection, as used herein, include an RF cable, an RF strap, an RF cylinder, an RF transmission line, and a combination of two or more thereof. To illustrate, the RF strap is elongated and flat. To further illustrate, the RF strap is rectangular in shape. As an illustration, the RF cable has an RF sheath and an RF conductor, and the RF transmission line has an RF rod and an RF sheath that surrounds the RF rod. An insulator is placed between the RF sheath and the RF rod of the RF transmission line.

The processor 120 is also coupled to the bias source system 114, which is coupled to the substrate support 124 via an RF communication medium 103. For example, when the bias source system 114 includes the bias RF generator and the bias impedance match matching network, the RF communication medium 103 is an RF transmission line. As another example, when the bias source system 114 includes the bias MPS and the bias reactive circuit, the RF communication medium 103 is an RF connection. The bias sensor 118 is coupled to the substrate support 124 to be associated with the substrate support 124 and the ring sensor 116 is coupled to the edge ring 126 to be associated with the edge ring 126. The ring sensor 116 and the bias sensor 118 are coupled to the processor 120 to provide feedback to the processor 120.

One or more of the RF coils 130 and 132 are supplied with RF power from one or more source RF systems. For example, the RF coil 130 is supplied with RF power from a first source RF system at one end of the RF coil 130 and an opposite end of the RF coil 130 is coupled to the ground potential. Similarly, the RF coil 132 is supplied with RF power from a second source RF system at one end of the RF coil 132 and an opposite end of the RF coil 132 is coupled to the ground potential. As another example, a single source RF system supplies RF power to both the RF coils 130 and 132. An example of a source RF system is a combination of a source RF generator and a source impedance matching circuit, and the source radio frequency generator is coupled to the source impedance matching circuit, which is coupled to a respective one of the RF coils 132 and 132. Another example of the source RF system is a matchless plasma source.

A substrate S is placed on a top surface of the substrate support 124. A central portion of the substrate S extends across the top surface of the substrate support 124 and an edge portion of the substrate S extends over the edge ring 126. The edge portion of the substrate S is peripheral to the central portion. An example of the substrate S is a semiconductor substrate, such as a semiconductor wafer. Another example of the substrate S is a dummy substrate. The processor 120 controls the bias source system 114 to generate an RF signal 134, which is supplied via the RF communication medium 103 to a lower electrode of the substrate support 124. An example of the RF signal 134 is a signal having a radio frequency, such as 400 kilohertz (kHz), or 1 megahertz (MHz), or 2 MHz, or 13 MHz. One or more process gases, such as an oxygen-containing gas, or a fluorine-containing gas, or a combination thereof, are provided to an inside volume of the plasma chamber 112. The inside volume is located between a horizontal level located at the substrate support 124 and the edge ring 126 and a horizontal level of the dielectric window 128.

When the RF signal 134 is supplied to the lower electrode of the substrate support 124 and the one or more process gases are supplied to the inside volume of the plasma chamber 112, plasma is generated within the inside volume to process the substrate S. Examples of processing the substrate S include etching the substrate S, depositing materials on the substrate S, and cleaning the substrate S.

While the substrate S is being processed, the bias sensor 118 generates a measurement signal 136 and sends the measurement signal 136 to the processor 120. An example of the measurement signal 136 is a voltage signal having amplitudes of voltage at the substrate support 124. Also, during processing of the substrate S, the ring sensor 116 generates a measurement signal 138 and sends the measurement signal 138 to the processor 120. An example of the measurement signal 138 is a voltage signal having amplitudes of voltage at the edge ring 126. As an example, an amplitude, as used herein, is a maximum amplitude or a zero-to-peak amplitude or a peak-to-peak amplitude.

The processor 120 receives the measurement signals 136 and 138, determines, such as identifies, a first stored parameter, such as a stored capacitance, of the resonator circuit 102, based on the amplitudes of the voltages of the measurement signals 136 and 138, and controls the resonator circuit 102 to achieve the first stored parameter. For example, the processor 120 receives a first amplitude of the measurement signal 138 and a second amplitude of the measurement signal 136, and calculates a ratio of the first and second amplitudes to generate a measured ratio. In the example, the processor 120 accesses the memory device 122 to identify a correspondence, such as a one-to-one relationship or a link, between a stored ratio of a ring voltage and a bias voltage and the first stored parameter of the resonator circuit 102. Further in the example, the processor 120 compares the stored ratio with the measured ratio to determine that the measured ratio is not within a predetermined ratio range from, such as equal to, the stored ratio to determine to control the resonator circuit 102 to achieve the first stored parameter. In the example, the processor 120 determines to control the resonator circuit 102 to achieve the first stored parameter until the measured ratio is within the predetermined ratio range from the stored ratio. To illustrate, the stored ratio ranges from 95% to 105%, and the measured ratio is 120% or 90%. To further illustrate, the stored ratio is 100%. In the example, the predetermined range is stored in the memory device 122.

Also in the example, upon determining to control the resonator circuit 102 to achieve the first stored parameter, the processor 120 controls the resonator circuit 102 to achieve the stored capacitance to further achieve the stored ratio. To illustrate, the processor 120 sends a control signal 105, indicating the stored capacitance, to the driver 106. In the illustration, upon receiving the control signal 105, the driver 106 generates a current signal based on the stored capacitance and sends the current signal to the motor 108. Further, in the illustration, in response to receiving the current signal, the motor 108 operates to modify a capacitance of the resonator circuit 102 to achieve the stored capacitance. The motor 108, in the illustration, operates to rotate a first plate of a capacitor of the resonator circuit 102 in relation a second plate of the capacitor to achieve the stored capacitance. Also, in the illustration, when the stored capacitance is achieved, the resonator circuit 102 outputs an RF signal 140, having RF power, is relation to the edge ring 126. When the RF signal 140 is output with respect to the edge ring 126, resonance is achieved between an inductive impedance of the resonator circuit 102 and a capacitive impedance of capacitance of the edge ring 126. In the illustration, the RF signal 140 is not actively supplied to the edge ring 126. Rather, in the illustration, the RF signal 140 modifies a voltage at the edge ring 126 to modify an amount of RF power that is received by the edge ring 126 via the substrate support 124 and the RF communication medium 103 from the bias source system 114. To further illustrate, there is no RF source system, such as an RF generator or a matchless plasma source, that is supplying RF power to the edge ring 126. Rather, in the illustration, a voltage is adjusted by the resonator circuit 102 at the edge ring 126, and the voltage produces the RF power represented as the RF signal 140. To further illustrate, there is no ring RF system, such as a matchless plasma source or a combination of a ring RF generator and a ring impedance matching circuit, actively supplying an RF signal to the edge ring 126.

In the illustration, a target ring voltage is achieved at the edge ring 126 to process the substrate S in a uniform manner across the top surface of the substrate S. To further illustrate, a predetermined number of features, such as channels, formed within the substrate S, are etched to achieve depths within a preset etch depth range to process the substrate S in the uniform manner. As another further illustration, a material is deposited across the top surface of the substrate to have a depth within a preset material depth range to process the substrate in the uniform manner. When the substrate S is processed in the uniform manner, uniformity, in the features, is achieved across the top surface of the substrate S.

In one embodiment, the capacitance of the resonator circuit 102 is not controlled by the controller 104 via the motor 108. For example, the resonator circuit 102 is not coupled to the motor 108. Before processing the substrate S, resonator circuit 102 has the stored capacitance to achieve the resonance between the inductive impedance of the resonator circuit 102 and capacitive impedance of the capacitance of the edge ring 126. For example, before the RF signal 134 is supplied to the substrate support 124 to process the substrate S, the capacitance of the resonator circuit 102 is adjusted manually to achieve the stored capacitance. In the example, after the stored capacitance is achieved, the processor 120 controls the bias source system 114 to generate the RF signal 134 to process the substrate S in the uniform manner.

In an embodiment, the RF coils 130 and 132 are supplied with RF power from the source RF systems. For example, the RF coil 130 is supplied with RF power from a first source RF system at one end of the RF coil 130 and an opposite end of the RF coil 130 is coupled to the ground potential. Similarly, the RF coil 132 is supplied with RF power from a second source RF system at one end of the RF coil 132 and an opposite end of the RF coil 132 is coupled to the ground potential.

In one embodiment, the plasma chamber 112 includes any number, such as one or three or four, of RF coils, and each of the RF coils includes any number of turns, such as two or four or five turns.

In an embodiment, the ring sensor 116 is coupled to a point on the RF connection 101 and the bias sensor 118 is coupled to a point on the RF communication medium 103.

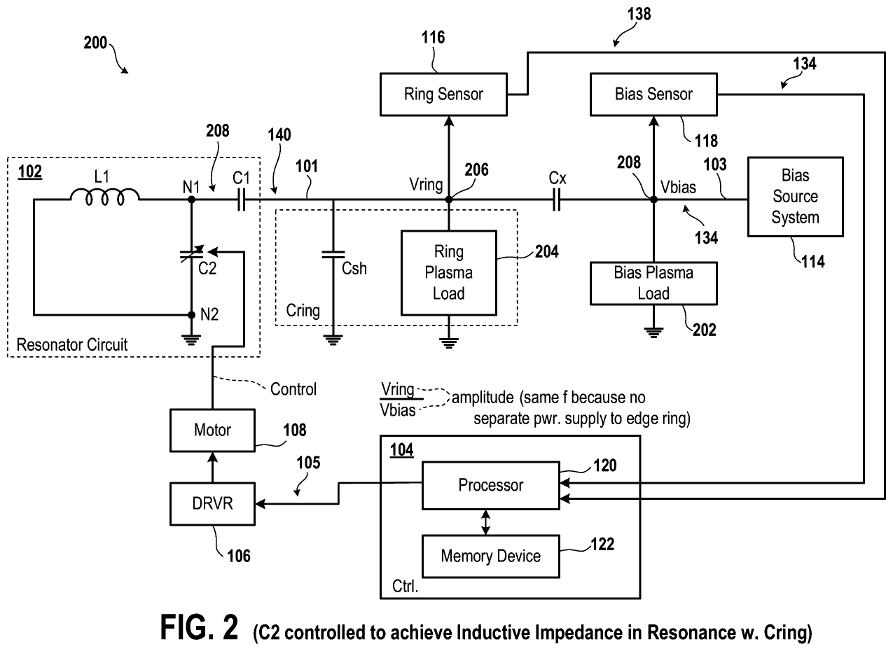

FIG. 2 is a diagram of an embodiment of a system 200 to illustrate details of the resonator circuit 102. The system 200 includes the resonator circuit 102, the ring sensor 116, the bias sensor 118, the bias source system 114, a bias plasma load 202, a ring plasma load 204, the controller 104, the driver 106, and the motor 108. An example of the ring plasma load 204 is the edge ring 126 (FIG. 1) and an example of the bias plasma load 202 is the substrate support 124 (FIG. 1).

The resonator circuit 102 includes an inductor L1, a capacitor C1, and a capacitor C2. An example of the capacitor C1 is a fixed capacitor and an example of the capacitor C2 is a variable capacitor. The capacitor C2 is coupled in parallel to the inductor L1. For example, a first end of the inductor L1 is coupled to a first end of the capacitor C2 at a node N1, and a second end of the inductor L1 and a second end of the capacitor C2 are coupled to each other at a node N2, which is at a ground potential.

Also, the parallel circuit of the inductor L1 and the capacitor C2 is coupled in series with the capacitor C1. For example, the node N1 is coupled to a first end of the capacitor C1 and a second end of the capacitor C1 is coupled to the ring plasma load 204. A stray capacitance between the edge ring 126 and a ground potential is represented as Csh in FIG. 2. For example, the ground potential is a potential of a side wall of the plasma chamber 112 (FIG. 1). Also, a total capacitance of the edge ring 126 and the stray capacitance is represented as Cring.

A term Vring represents a voltage, such as an amplitude of voltage, of the ring plasma load 204 to be associated with the ring plasma load 204. For example, the voltage Vring is a voltage at a point 206 on the RF connection 101. In the example, the ring sensor 116 is coupled to the point 206. Similarly, a term Vbias represents a voltage, such as an amplitude of voltage, of the bias plasma load 202 to be associated with the bias plasma load 202. For example, the voltage Vbias is a voltage at a point 208 on the RF communication medium 103. A capacitance between the ring plasma load 204 and the bias plasma load 202 is represented as Cx. For example, the edge ring 226, the substrate support 224, and a gap between the edge ring 226 and the substrate support 224 creates the capacitance Cx between the edge ring 226 and the substrate support 224. As another example, the ring plasma load 204 receives a portion of RF power supplied to the bias plasma load 202 based on the capacitance Cx.

Upon receiving the measurement signals 138 and 136, the processor 120 controls the capacitor C2 to achieve the stored capacitance. For example, the processor 120 sends the control signal 105 to the driver 106, and the driver 106 sends the current signal, generated based on the control signal 105, to the motor 108. The motor 108 operates to modify a capacitance of the capacitor C2 to the stored capacitance. When the capacitance of the capacitor C2 is modified to the stored capacitance, an impedance of the node N1 is modified by an inductance of the inductor L1 and the capacitance of the capacitor C2 to output an RF signal 208 at the node N1. An impedance of the RF signal 208 is modified by a capacitance of the capacitor C1 to output the RF signal 140. The RF signal 140 creates a voltage at an output of the resonator circuit 102 and RF power of the voltage is applied via the RF connection 101 and the point 206 to the ring plasma load 204 to process the substrate S (FIG. 1) in the uniform manner. It should be noted that there is no need for frequency matching and phase matching because RF power is not being actively supplied to the ring plasma load 204.

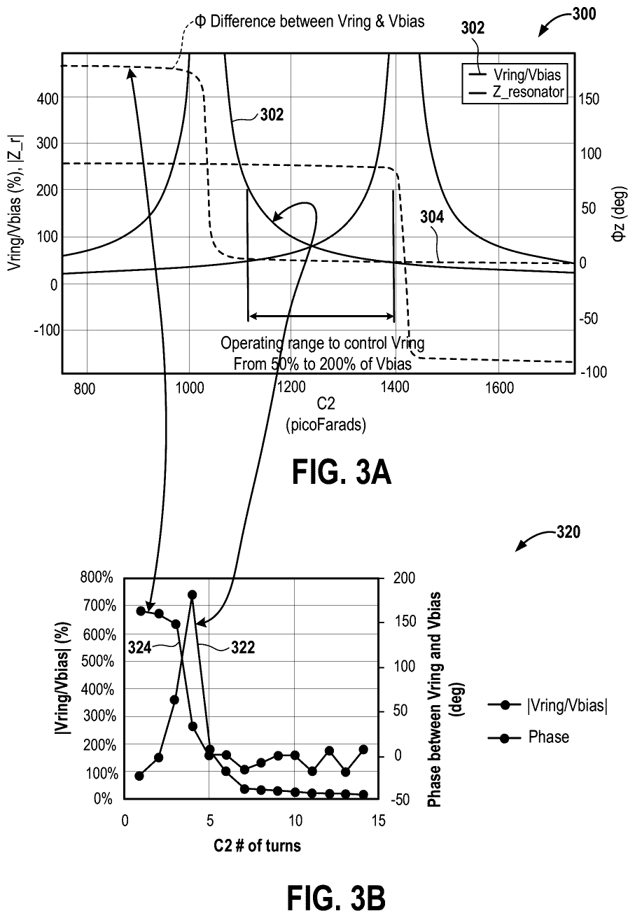

FIG. 3A is an embodiment of a graph 300 to illustrate a control of the capacitance of the capacitor C2 to achieve a percentage ratio between the voltages Vring and Vbias, such as amplitudes of the voltages Vring and Vbias. The graph 300 plots model data of the percentage ratio on a first y-axis, a phase difference oz on a second y-axis, and the capacitance of the capacitor C2 on an x-axis. The graph 300 includes a plot 302 of the percentage ratio between the voltages Vring and Vbias, and a plot 304 of the phase difference oz between phases of the voltages Vring and Vbias. By controlling the capacitance of the capacitor C2, the percentage ratio between the voltages Vring and Vbias varies from 50% to 200% while the phase difference between the voltages Vring and Vbias is maintained to be zero. As such, based on the measurement signals 138 and 136, the capacitance of the capacitor C2 is modified to control ratios of amplitudes of the voltages Vring and Vbias.

FIG. 3B is an embodiment of a graph 320 to illustrate a control of the capacitance of the capacitor C2 to achieve a percentage ratio between the voltages Vring and Vbias, such as amplitudes of the voltages Vring and Vbias. The graph 320 plots experimental data of the percentage ratio on a y-axis and a number of turns of the capacitor C2 on an x-axis. The number of turns of the capacitor C2 represents the capacitance of the capacitor C2. Based on the measurement signals 138 and 136 (FIG. 1), the capacitance of the capacitor C2 is modified to change the percentage ratio of the amplitudes of the voltages Vring and Vbias.

The graph 320 includes a plot 322 of the percentage ratio between the voltages Vring and Vbias, and a plot 324 of the phase difference oz between the phases of the voltages Vring and Vbias. By controlling the capacitance of the capacitor C2, the percentage ratio between the voltages Vring and Vbias varies from 100% to 200% while the phase difference between the voltages Vring and Vbias is within a predetermined range from zero, such as substantially zero. An example of the predetermined range from zero is the phase difference that ranges from −25 to −50.

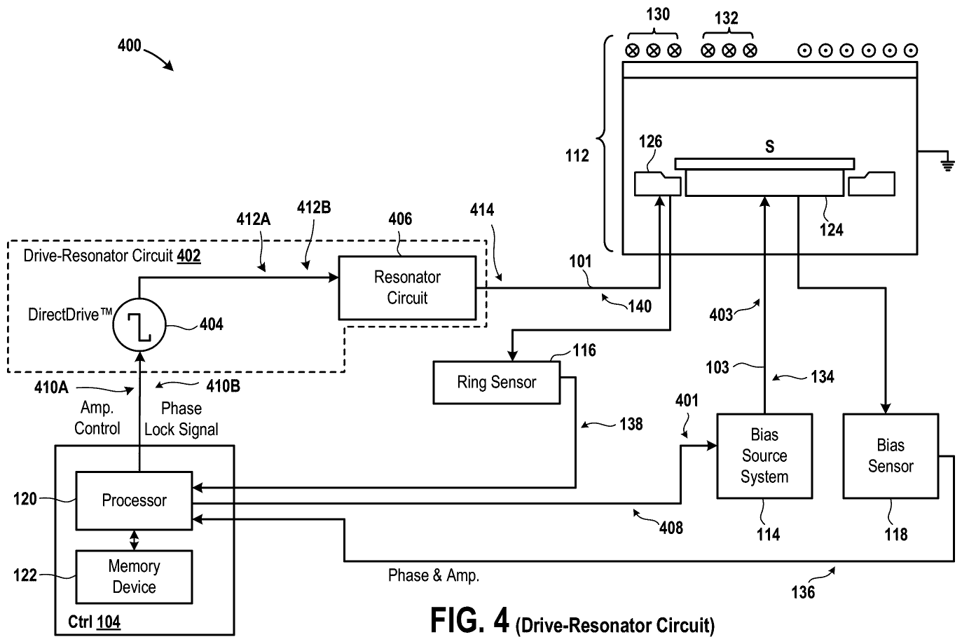

FIG. 4 is a diagram of an embodiment of a system 400 to illustrate a drive-resonator circuit 402. The system 400 includes the drive-resonator circuit 402, the plasma chamber 112, the bias sensor 118, the bias source system 114, the controller 104, and the ring sensor 116.

The drive-resonator circuit 402 includes a matchless plasma source 404, such as the DirectDrive™, and a resonator circuit 406. The processor 120 is coupled to the matchless plasma source 404, which is coupled to the resonator circuit 406. The resonator circuit 406 is coupled via the RF connection 101 to the edge electrode 126.

The processor 120 generates a frequency control signal 408 indicating a frequency of operation of the bias source system 114 and sends the frequency control signal 408 to the bias source system 114. For example, the frequency of operation is of the bias RF generator or of the bias MPS. To illustrate, the frequency of operation is 400 kHz, or 1 MHz, or 2 MHz, or 13 MHz.

Upon receiving the frequency control signal 408, the bias source system 114 generates the RF signal 134 having a frequency indicated by the frequency of operation. For example, the bias RF generator generates an RF signal (not shown) having the same frequency as that of the frequency of operation of the bias RF generator, and sends the RF signal to the bias impedance matching circuit. In the example, upon receiving the RF signal, the bias impedance matching circuit matches an impedance of a load coupled to an output of the bias impedance matching circuit with an impedance of a source coupled to an input of the bias impedance matching circuit to generate the RF signal 134. In the example, the load includes the RF communication medium 103 and the substrate support 124, and the source includes the bias RF generator and an RF cable that connects the bias RF generator to the bias impedance matching circuit. As another example, a signal generator of the bias MPS generates an RF signal, such as a square wave signal or a square waveform, which is processed by remaining components of the bias MPS and the bias reactive circuit, such as a junction box with reactive elements, to generate the RF signal 134 having the same frequency as that of the frequency of operation indicated within the frequency control signal 408.

Moreover, the processor 120 generates a control signal 410A indicating that a frequency of operation of the MPS 404 be the same as, such as equal to, the frequency of operation of the bias source system 114. For example, the control signal 410A indicates the same frequency of operation as that of the frequency of operation of the bias source system 114. A predetermined frequency, such as the frequency of operation of the bias source system 114, is stored in the memory device 122. The processor 120 sends the control signal 410A to the MPS 404. Upon receiving the control signal 410A, the MPS 404 generates an RF signal 412A, such as a square wave signal or a square waveform, having the same frequency as that of the frequency of operation received within the control signal 410A and sends the RF signal 412A to the resonator circuit 406.

The resonator circuit 406 filters the RF signal 412A to output an RF signal 414, and the RF signal 414 produces an RF voltage, which is applied via the RF connection 101 to the edge ring 126. For example, the RF signal 414 is not actively supplied to the edge ring 126. Rather, in the example, the RF signal 414 modifies a voltage at the edge ring 126 to modify an amount of RF power that is received by the edge ring 126 via the substrate support 124 and the RF communication medium 103 from the bias source system 114.

When the one or more process gases are supplied to the plasma chamber 112 in addition to the RF signals 134 and 414, plasma is generated or maintained within the inside volume of the plasma chamber 112. During a time period in which the plasma is generated or maintained, the bias sensor 118 generates the measurement signal 136 and the ring sensor 116 generates the measurement signal 138.

The processor 120 receives the measurement signals 136 and 130, and determines whether there is a phase difference between phases of the measurement signals 138 and 136. For example, the processor 120 determines a first time at which the measurement signal 138 has a first voltage value and has a positive slope and a second time at which the measurement signal 138 has a second voltage value and has a negative slope after removing its direct current (DC) component. Also, in the example, the processor 120 determines a primary time at which the measurement signal 136 has the first voltage value and has a positive slope and a secondary time at which the measurement signal 138 has the second voltage value and has a negative slope after removing its DC component. Further in the example, the processor 120 determines that there is a first time difference between the first and primary times or a second time difference between the second and secondary times or the first and second time differences exist to determine that there is the phase difference between the phase of the measurement signal 138 and the phase of the measurement signal 136. In the example, the first time difference or the second time difference is an example of the phase difference. On the other hand, in the example, the processor 120 determines that there is no time difference between the first and primary times and no time difference between the second and secondary times to determine that there is no phase difference between the phase of the measurement signal 138 and the phase of the measurement signal 136.

Upon determining that the phase difference between the phases of the measurement signals 138 and 136 exists, the processor 120 generates a control signal 410B including a value of a phase of the RF signal 140 to be generated by the drive-resonator circuit 402 or generates a phase control signal 401 including a value of a phase of an RF signal 403 to be output from the bias source system 114 or a combination thereof. For example, the processor 120 controls the MPS 404 to modify the phase of the RF signal 140 to bring the phase difference between the phases of the measurement signals 138 and 136 to be within a predetermined phase range stored in the memory device 122. To illustrate, the processor 120 determines the phase of the RF signal 140 to reduce the phase difference between the phases of the measurement signals 130 and 136 to zero or to a predetermined value within the predetermined phase range, and embeds a value of the phase within the control signal 410B. In the example, instead of or in addition to controlling the MPS 404 to modify the phase of the RF signal 140, the processor 120 controls the bias source system 114 to modify the phase of the RF signal 134. When the phase of the RF signal 134 is modified, the phase difference between the phases of the measurement signals 138 and 136 is within the predetermined phase range. In the example, the processor 120 controls the phase of the RF signal 140 or of the RF signal 134 or a combination thereof until the phase difference between the phases of the measurement signals 138 and 136 is within the predetermined phase range.

Moreover, upon receiving the measurement signals 138 and 136, the processor 120 determines, such as identifies, a second stored parameter, such as a stored voltage or an amplitude of the stored voltage, of a RF signal 412B, such as a square waveform or a square wave signal, to be output from the MPS 404, based on the amplitudes of the voltages of the measurement signals 136 and 138, and controls the MPS 404 to achieve the second stored parameter. For example, the processor 120 calculates the ratio of the first amplitude of the measurement signal 138 and the second amplitude of the measurement signal 136 to generate the measured ratio. In the example, the processor 120 accesses the memory device 122 to identify a correspondence, such as a one-to-one relationship or a link, between a stored ratio of the ring voltage and the bias voltage and the second stored parameter of the RF signal 412B to be output from the MPS 404. Further in the example, the processor 120 compares the stored ratio with the measured ratio to determine that the measured ratio is not within the predetermined ratio range from the, such as equal to, the stored ratio to determine to control the MPS 404 to achieve the second stored parameter. In the example, the processor 120 determines to control the MPS 404 to achieve the second stored parameter until the measured ratio is within the predetermined ratio range from the stored ratio. Further, in the example, the processor 120 determines not to control the MPS 404 to achieve the second stored parameter upon determining that the measured ratio is within the predetermined ratio range from the stored ratio. The processor 120 includes within the control signal 410B the second stored parameter of the RF signal 412B.

Upon receiving the control signal 410B, the MPS 404 modifies a phase and an amplitude of the RF signal 412A to output the RF signal 412B having the second stored parameter, having the value of the phase of the RF signal 140, and having the same frequency as that of the RF signal 412A. The resonator circuit 406 receives the RF signal 412B and resonates to output the RF signal 140. The voltage is the RF signal 140 is applied from the resonator circuit 406 via the RF connection 101 to the edge ring 126 for processing the substrate S in the uniform manner.

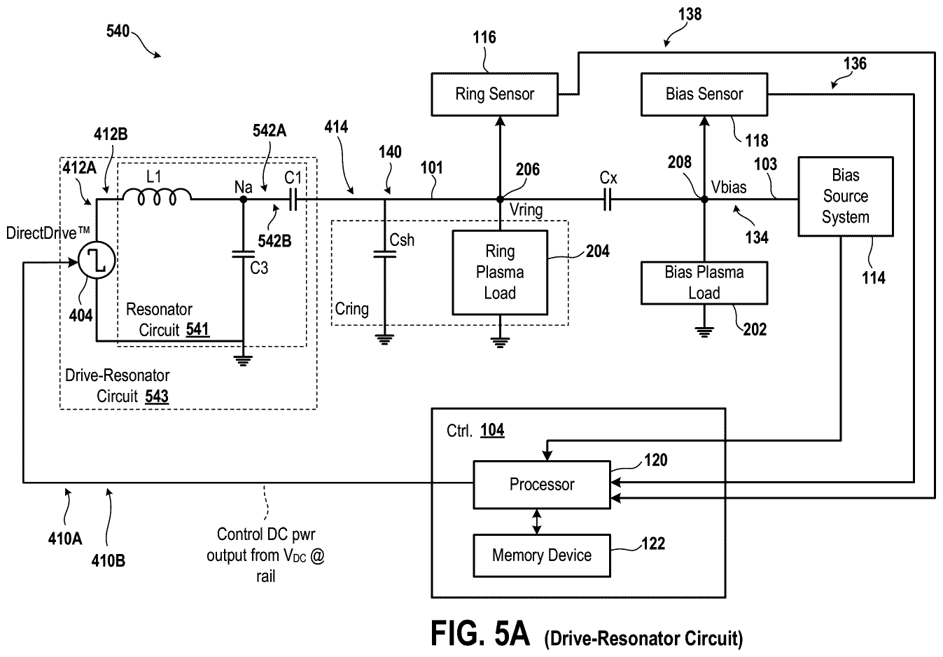

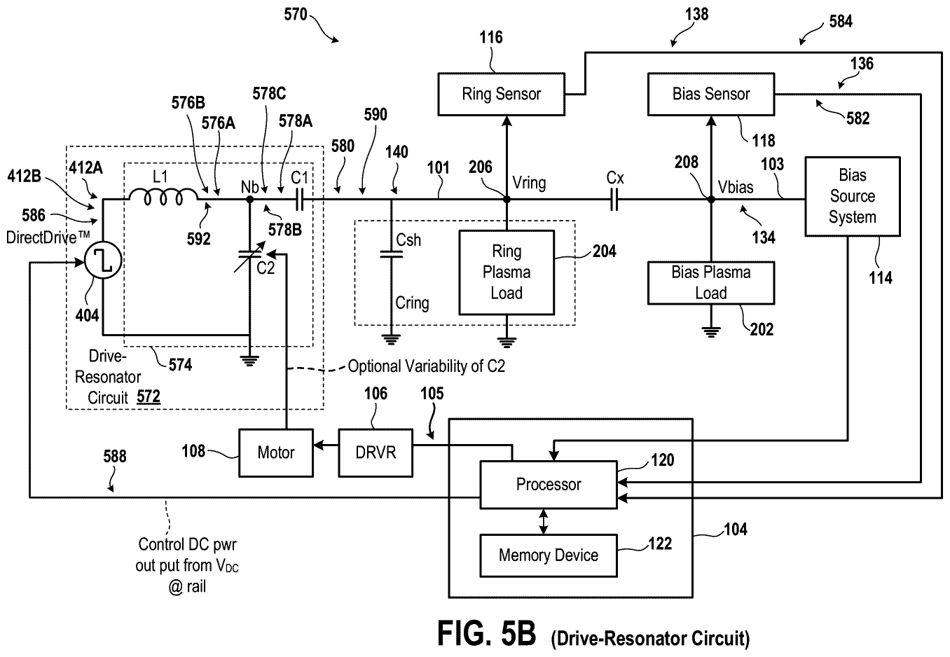

FIG. 5A is a diagram of an embodiment of a system 540 to illustrate details of a resonator circuit 541, which is an example of the resonator circuit 406 (FIG. 4). The system 540 includes a drive-resonator circuit 543, the ring sensor 116, the bias sensor 118, the bias source system 114, the bias plasma load 202, the ring plasma load 204, and the controller 104. The drive-resonator circuit 543 is an example of the drive-resonator circuit 402 (FIG. 4). The drive-resonator circuit 543 includes the resonator circuit 541 and the MPS 404.

The resonator circuit 541 includes the inductor L1, the capacitor C1, and a capacitor C3, which is a fixed capacitor. As an example, a capacitance of the capacitor C3 is equal to a capacitance of the capacitor C2 (FIG. 2). As another example, the capacitance of the capacitor C3 is different from the capacitance of the capacitor C2. The capacitor C3 forms a parallel circuit with a series circuit of the inductor L1 and the MPS 404. For example, the first end of the inductor L1 is coupled at a node Na to a first end of the capacitor C3 and the second end of the inductor L1 is coupled to an output of the MPS 404. A second end of the capacitor C3 is coupled to the ground potential, which is coupled to the MPS 404. Also, the node Na is coupled to the capacitor C1, which is coupled via the RF connection 101 and the point 206 to the ring plasma load 204.

Upon receiving the RF signal 412A, the inductor L1 and the capacitor C3 filters the RF signal 412A to output an RF signal 542A. For example, the inductor L1 reduces, such as removes, one or more harmonic frequencies from the RF signal 412A to output the RF signal 542A at the node Na. Moreover, upon receiving the RF signal 542A from the node Na, the capacitor C1 changes an impedance of the RF signal 542A to output the RF signal 414. An RF voltage of the RF signal 414 is applied via the RF connection 101 and the point 206 to the ring plasma load 204 for processing the substrate S.

Similarly, upon receiving the RF signal 412B, the inductor L1 and the capacitor C3 filters the RF signal 412B to output an RF signal 542B. As an example, the inductor L1 reduces, such as removes, one or more harmonic frequencies from the RF signal 412B to output the RF signal 542B at the node Na. Moreover, in response to receiving the RF signal 542B from the node Na, the capacitor C1 changes an impedance of the RF signal 542B to output the RF signal 140. The RF voltage of the RF signal 140 is applied via the RF connection 101 and the point 206 to the ring plasma load 204 for processing the substrate S in the uniform manner.

FIG. 5B is a diagram of an embodiment of a system 570 to illustrate the use of both the capacitor C2 and the MPS 404 to generate the RF signal 140. The system 570 includes a drive-resonator circuit 572, the ring sensor 116, the bias sensor 118, the bias source system 114, the bias plasma load 202, the ring plasma load 204, the controller 104, the driver 106, and the motor 108. The drive-resonator circuit 572 is an example of the drive-resonator circuit 402 (FIG. 4). The drive-resonator circuit 572 includes a resonator circuit 574 and the MPS 404. The resonator circuit 574 is an example of the resonator circuit 406 (FIG. 4).

The resonator circuit 574 includes the inductor L1, the capacitor C1, and the capacitor 2. The capacitor C2 forms a parallel circuit with a series circuit of the inductor L1 and the MPS 404. For example, the first end of the inductor L1 is coupled at a node Nb to the first end of the capacitor C2 and the second end of the inductor L1 is coupled to the output of the MPS 404. The second end of the capacitor C2 is coupled to the ground potential, which is coupled to the MPS 404. Also, the node Nb is coupled to the capacitor C1.

Upon receiving the RF signal 412A, the inductor L1 modifies an impedance of the RF signal 412A to output an RF signal 576A. For example, the inductor L1 reduces, such as removes, one or more harmonic frequencies from the RF signal 412A to output the RF signal 576A at the node Nb. Moreover, upon receiving the measurement signals 138 and 136, the processor 120 controls the capacitor C2 to achieve the stored capacitance. For example, the processor 120 sends the control signal 105 to the driver 106, and the driver 106 sends the current signal, generated based on the control signal 105, to the motor 108. The motor 108 operates to modify a capacitance of the capacitor C2 to the stored capacitance. When the capacitance of the capacitor C2 is modified to the stored capacitance, an impedance of the RF signal 576A output from the inductor L1 is modified to output an RF signal 578A from the node Nb. Also, an impedance of the RF signal 578A is modified by a capacitance of the capacitor C1 to output the RF signal 140. The RF voltage of the RF signal 414 is applied from the capacitor C1 via the RF connection 101 and the point 206 to the ring plasma load 204 for processing the substrate S in the uniform manner.

Moreover, upon receiving the RF signal 412B, the inductor L1 modifies an impedance of the RF signal 412B to output an RF signal 576B. As an example, the inductor L1 reduces, such as removes, one or more harmonic frequencies from the RF signal 412B to output the RF signal 576B at the node Nb. Moreover, the capacitor C2 is controlled to achieve the stored capacitance. When the capacitance of the capacitor C2 is modified to the stored capacitance, an impedance of the RF signal 576B output from the inductor L1 is modified to output an RF signal 578B from the node Nb. Also, an impedance of the RF signal 578B is modified by a capacitance of the capacitor C1 to output an RF signal 580. An RF voltage of the RF signal 580 is applied from the capacitor C1 via the RF connection 101 and the point 206 to the ring plasma load 204 for processing the substrate S in the uniform manner.

Furthermore, after the RF signal 580 is generated, during a time period in which the capacitor C2 is controlled to have the stored capacitance, the bias sensor 118 generates a measurement signal 582 and sends the measurement signal 582 to the processor 120 and the ring sensor 116 generates a measurement signal 584 and sends the measurement signal 584 to the processor 120. An example of the measurement signal 582 is a voltage signal indicating a voltage at the point 206 and an example of the measurement signal 582 is a voltage signal indicating a voltage at the point 208.

Furthermore, upon receiving the measurement signals 582 and 584, the processor 120 determines, such as identifies, the second stored parameter, such as the voltage, of an RF signal 586, such as a square waveform or a square wave signal, to be output from the MPS 404, based on the amplitudes of the voltages of the measurement signals 584 and 582, and controls the MPS 404 to achieve the second stored parameter. For example, the processor 120 calculates a ratio of a first amplitude of the measurement signal 584 and a second amplitude of the measurement signal 582 to generate a measured ratio. In the example, the processor 120 accesses the memory device 122 to identify a correspondence, such as a one-to-one relationship or a link, between the stored ratio of the ring voltage and the bias voltage and the second stored parameter of the RF signal 586 to be output from the MPS 404. Further in the example, the processor 120 compares the stored ratio with the measured ratio to determine that the measured ratio is not within the predetermined ratio range from, such as equal to, the stored ratio to determine to control the MPS 404 to achieve the second stored parameter. In the example, the processor 120 determines to control the MPS 404 to achieve the second stored parameter until the measured ratio is within the predetermined ratio range from the stored ratio. The processor 120 generates and includes within a control signal 588 the second stored parameter of the RF signal 586.

The processor 120 receives the measurement signals 584 and 582, and determines whether there is a phase difference between phases of the measurement signals 584 and 582 in the same manner in which the processor 120 determines whether there is a phase difference between the measurement signals 138 and 136. Upon determining that the phase difference between the phases of the measurement signals 584 and 582 exists, the processor 120 generates the control signal 588 including a value of a phase of an RF signal 590 to be output at the drive-resonator circuit 572. For example, the processor 120 determines the phase of the RF signal 590 to bring the phase difference between the phases of the measurement signals 584 and 582 to be within the predetermined phase range. To illustrate, the processor 120 determines the phase of the RF signal 590 to reduce the phase difference between the phases of the measurement signals 584 and 582 to zero or to the predetermined value within the predetermined phase range, and embeds a value of the phase within the control signal 588.

Upon receiving the control signal 588, the MPS 404 modifies a phase and an amplitude of the RF signal 412B to output the RF signal 586 having the second stored parameter, having the value of the phase of the RF signal 590, and having the same frequency as that of the RF signal 412A. The resonator circuit 574 receives the RF signal 586 and resonates to output the RF signal 590. For example, upon receiving the RF signal 586, the inductor L1 modifies an impedance of the RF signal 586 to output an RF signal 592. As an example, the inductor L1 reduces, such as removes, one or more harmonic frequencies from the RF signal 586 to output the RF signal 592 at the node Nb. Moreover, the capacitor C2 is controlled to achieve the stored capacitance. When the capacitance of the capacitor C2 is modified to the stored capacitance, an impedance of the RF signal 592 output from the inductor L1 is modified to output an RF signal 578C from the node Nb. Also, an impedance of the RF signal 578C is modified by a capacitance of the capacitor C1 to output the RF signal 590.

An RF voltage of the RF signal 590 is applied from the resonator circuit 574 via the RF connection 101 to the edge ring 126 for processing the substrate S in the uniform manner. In this manner, an amplitude or phase or a combination thereof of the RF signal 412B is modified while maintaining the stored capacitance of the capacitor C2 to process the substrate S in the uniform manner.

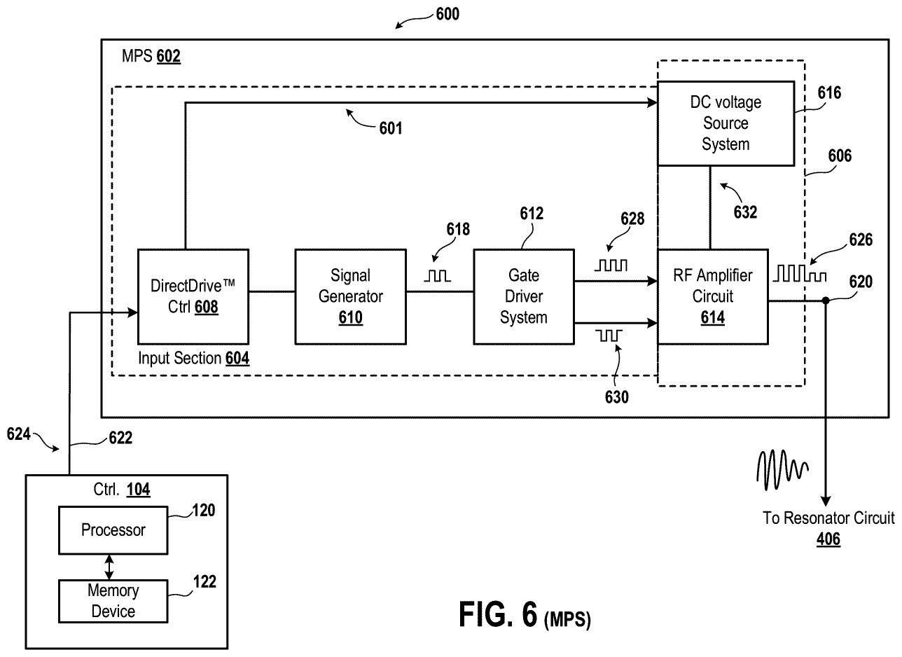

FIG. 6 is a diagram of an embodiment of a system 600 to illustrate details of an MPS 602, which is an example of the MPS 404 (FIG. 4). The system 600 includes the controller 104 and the MPS 602. The MPS 602 includes an input section 604 and an output section 606. The input section 604 includes an MPS controller 608, a signal generator 610, and a gate driver system 612. The output section includes an RF amplifier circuit 614 and DC voltage source system 616. The DC voltage source system 616 is sometimes referred to herein as a DC rail.

An example of the signal generator 610 is a square wave oscillator that generates a square wave signal 618, such as a square waveform, which is a digital waveform or a pulse train. The square waveform pulses periodically and has square-shaped pulses. For example, the square waveform transitions during each cycle of a clock signal between a first logic level, such as high or one, and a second logic level, such as low or zero. The signal generator 306 generates the square wave signal 618 at the frequency of operation of the MPS 602. An example of the gate driver system 612 includes a combination of a pass-through gate and a NOT gate. An example of the RF amplifier circuit 614 is a half-bridge circuit. To illustrate, the half-bridge circuit has a first transistor and a second transistor, and both the first and second transistors are coupled to each other at an output 620 of the MPS 602. To further illustrate, a drain terminal of the first transistor is coupled to the DC voltage source system 616, a source terminal of the first transistor is coupled via the output 620 to a drain terminal of the second transistor, and a source terminal of the second transistor is coupled to the ground potential. Also, the pass-through gate of the gate driver system 612 is coupled to a gate terminal of the first transistor and the NOT gate of the gate driver system 612 is coupled to a gate terminal of the second transistor. The output 620, which is an output of the RF amplifier circuit 614 is between the source terminal of the first transistor and the drain terminal of the second transistor.

The processor 120 is coupled to the MPS controller 608 via a transfer cable 622, such as a serial transfer cable, a parallel transfer cable, or a universal serial bus (USB) cable. The MPS controller 608 is coupled to the signal generator 610. The signal generator 610 is coupled to inputs of the pass-through and NOT gates of the gate driver system 612. An output of the pass-through gate and an output of the NOT gate is coupled to the FET circuit 614. The FET circuit 614 is coupled to the DC voltage source system 616 and the output 620 is coupled to the resonator circuit 406.

The MPS controller 608 receives a control signal 624 from the processor 120 via the transfer cable 622. The control signal 624 is an example of the control signal 410A, 410B, or 588 (FIGS. 4 and 5B). Upon receiving the control signal 624, the MPS controller 608 identifies, from the control signal 624, one or more of a frequency of an RF signal 626 to be generated by the MPS 602, an amplitude of the RF signal 626, and a phase of the RF signal 626. The RF signal 626 is an example of the RF signal 412A, or 412B, or 586 (FIG. 5B). The frequency of the RF signal 626 to be generated is the same as a frequency of operation of the signal generator 610.

The MPS controller 608 provides the frequency and the phase of the RF signal 626 to be generated to the signal generator 610. Also, based on the amplitude of the RF signal 626 to be generated, the MPS controller 608 generates a shaping control signal 601 indicating the amplitude, and sends the shaping control signal 601 to the DC voltage source system 616.

Upon receiving the frequency and the phase of the RF signal 626 to be generated, the signal generator 610 generates the square wave signal 618 having the frequency and the phase, and provides the square wave signal 618 to the gate drivers of the gate driver system 612. The pass-through gate of the gate driver system 612 passes through an amplitude of the square wave signal 618 to output a square wave signal 628 having the frequency and the phase indicated within the control signal 624. The NOT gate of the gate driver system 612 inverts the square wave signal 618 to output an inverted signal 630, which is also a square wave signal. The inverted signal 630 has the same frequency as that indicated in the control signal 624 and a phase that is 180 degrees out of phase with the phase of the square wave signal 628. Additional dead time between the signals 628 and 630 is provided to avoid shoot through fault.

The signals 628 and 630 are provided to the gate terminals of the RF amplifier circuit 614. The first transistor of the RF amplifier circuit 614 turns on and off according to the square wave signal 628 and the second transistor of the RF amplifier circuit 614 turns on and off according to the inverted signal 630 to output an amplified square wave signal at the output 620 of the RF amplifier 614. The amplified square wave signal is pulsed to have the frequency indicated within the control signal 624 and the phase indicated within the control signal 624.

Upon receiving the shaping control signal 601, the DC voltage source system 616 provides a voltage signal 632 based on the amplitude indicated with the shaping control signal 601 to the RF amplifier circuit 614. The voltage signal 632 has the amplitude indicated with the shaping control signal 601. Power of the amplified square wave signal output from the RF amplifier circuit 614 is pulsed to have the amplitude of the voltage signal 632, the frequency indicated within the control signal 624, and the phase indicated within the control signal 624.

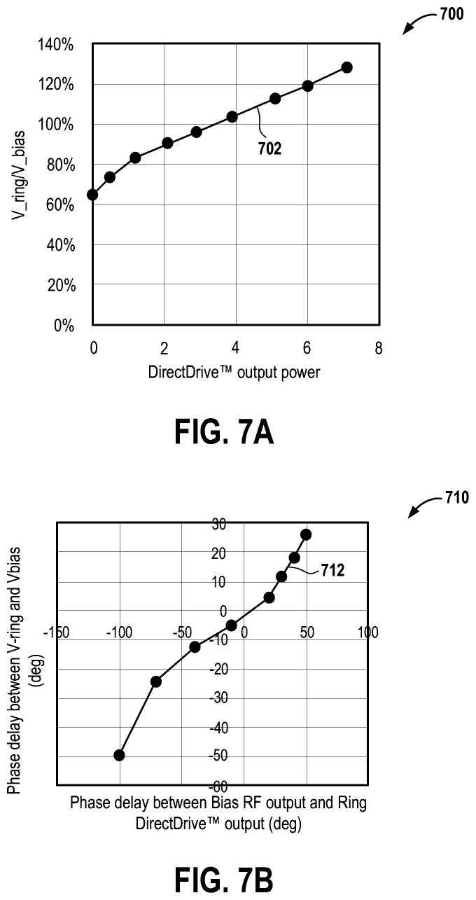

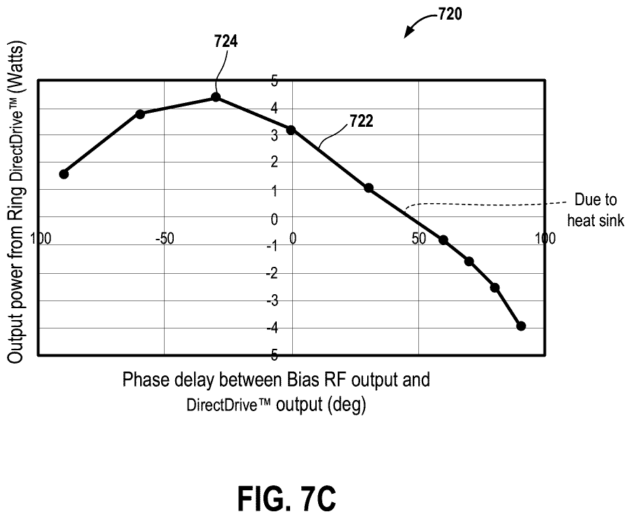

FIG. 7A is an embodiment of a graph 700 to illustrate that a ratio of amplitudes of the Vring to the amplitude of the Vbias is controlled by modifying, such as increasing or decreasing, an amplitude of the RF signal 626 (FIG. 6). The graph 700 includes a plot 702 of the ratio of the amplitude of the Vring to the amplitude of the Vbias on a y-axis and amplitudes of power of the RF signal 626 output from the MPS 602 (FIG. 6) on an x-axis. By increasing the amplitude of the power of the RF signal 626 output from the MPS 602, the ratio of the amplitude of the Vring to the amplitude of the Vbias increases and by decreasing the amplitude of the power of the RF signal 626, the ratio of the amplitude of the Vring to the amplitude of the Vbias decreases.

FIG. 7B is an embodiment of a graph 710 to illustrate that a phase delay between a phase of the Vring and a phase of the Vbias is controlled by modifying, such as increasing or decreasing, a phase delay between a phase of the RF signal 134 generated by the bias source system 114 (FIG. 1) and a phase of the RF signal 626 (FIG. 6). The graph 710 includes a plot 712 of the phase delay between the phase of the Vring and the phase of the Vbias on a y-axis and the phase delay between the phase of the RF signal 134 generated by the bias source system 114 and the phase of the RF signal 626 on an x-axis. As illustrated, by increasing the phase delay between the phase of the RF signal 134 generated by the bias source system 114 and the phase of the RF signal 626, there is an increase in the phase delay between the phase of the Vring and the phase of the Vbias and by decreasing the phase delay between the phase of the RF signal 134 generated by the bias source system 114 and the phase of the RF signal 626, there is a decrease in the phase delay between the phase of the Vring and the phase of the Vbias.

FIG. 7C is an embodiment of a graph 720 to illustrate that RF power output from the MPS 602 (FIG. 6) is a function of a phase delay between a phase of the RF signal 134 (FIG. 1) generated by the bias source system 114 (FIG. 1) and a phase of the RF signal 626 (FIG. 6). The graph 720 includes a plot 722 of the RF power output from the MPS 602 on a y-axis and the phase delay between the phase of the RF signal 134 and the phase of the RF signal 626 on an x-axis. As shown in the plot 720, with an increase in the phase delay, there is a decrease in the RF power output from the MPS 602 and with a decrease in the phase delay, there is an increase in the RF power output from the MPS 602 until a point 724 on the plot 722. After the point 724, with a further decrease in the phase delay, there is a decrease in the RF power output from the MPS 602.

It should be noted that the MPS 404 (FIG. 4) can take power away from the resonator circuit 541 or 572 (FIGS. 5A and 5B). For example, when a voltage at the DC rail (FIG. 6) is lower than a voltage at the output of the MPS 404, because the resonator circuit 541 or 572 is powered from the bias source system 114, the DC rail charges through the first transistor, which is a top transistor, in the RF amplifier circuit 614 (FIG. 6) when the first transistor turns on. This will result in a negative output power from the MPS 404. It is also possible to use this effect to gain further control over the ring voltage with additional circuit on the DC rail that controls power dissipation and/or diversion.

Embodiments described herein may be practiced with various computer system configurations including hand-held hardware units, microprocessor systems, microprocessor-based or programmable consumer electronics, minicomputers, mainframe computers and the like. The embodiments can also be practiced in distributed computing environments where tasks are performed by remote processing hardware units that are linked through a network.

In some embodiments, a controller, described herein, is a part of a system, which may be part of the above-described examples. Such systems include semiconductor processing equipment, including a processing tool or tools, chamber or chambers, a platform or platforms for processing, and/or specific processing components (a wafer pedestal, a gas flow system, etc.). These systems are integrated with electronics for controlling their operation before, during, and after processing of a semiconductor wafer or substrate. The electronics is referred to as the “controller,” which may control various components or subparts of the system or systems. The controller, depending on the processing requirements and/or the type of system, is programmed to control any of the processes disclosed herein, including the delivery of process gases, temperature settings (e.g., heating and/or cooling), pressure settings, vacuum settings, power settings, RF generator settings, RF matching circuit settings, frequency settings, flow rate settings, fluid delivery settings, positional and operation settings, wafer transfers into and out of a tool and other transfer tools and/or load locks coupled to or interfaced with a system.

Broadly speaking, in a variety of embodiments, the controller is defined as electronics having various integrated circuits, logic, memory, and/or software that receive instructions, issue instructions, control operation, enable cleaning operations, enable endpoint measurements, and the like. The integrated circuits include chips in the form of firmware that store program instructions, digital signal processors (DSPs), chips defined as ASICs, PLDs, and/or one or more microprocessors, or microcontrollers that execute program instructions (e.g., software). The program instructions are instructions communicated to the controller in the form of various individual settings (or program files), defining the parameters, the factors, the variables, etc., for carrying out a particular process on or for a semiconductor wafer or to a system. The program instructions are, in some embodiments, a part of a recipe defined by process engineers to accomplish one or more processing steps during the fabrication of one or more layers, materials, metals, oxides, silicon, silicon dioxide, surfaces, circuits, and/or dies of a wafer.

The controller, in some embodiments, is a part of or coupled to a computer that is integrated with, coupled to the system, otherwise networked to the system, or a combination thereof. For example, the controller is in a “cloud” or all or a part of a fab host computer, which allows for remote access of the wafer processing. The computer enables remote access to the system to monitor current progress of fabrication operations, examines a history of past fabrication operations, examines trends or performance metrics from a plurality of fabrication operations, to change parameters of current processing, to set processing steps to follow a current processing, or to start a new process.

In some embodiments, a remote computer (e.g. a server) provides process recipes to a system over a network, which includes a local network or the Internet. The remote computer includes a user interface that enables entry or programming of parameters and/or settings, which are then communicated to the system from the remote computer. In some examples, the controller receives instructions in the form of data, which specify the parameters, factors, and/or variables for each of the processing steps to be performed during one or more operations. It should be understood that the parameters, factors, and/or variables are specific to the type of process to be performed and the type of tool that the controller is configured to interface with or control. Thus as described above, the controller is distributed, such as by including one or more discrete controllers that are networked together and working towards a common purpose, such as the processes and controls described herein. An example of a distributed controller for such purposes includes one or more integrated circuits on a chamber in communication with one or more integrated circuits located remotely (such as at the platform level or as part of a remote computer) that combine to control a process on the chamber.

Without limitation, in various embodiments, example systems to which the methods are applied include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that is associated or used in the fabrication and/or manufacturing of semiconductor wafers.

It is further noted that in some embodiments, the above-described operations apply to several types of plasma chambers, e.g., a plasma chamber including an inductively coupled plasma (ICP) reactor, a capacitively coupled plasma (CCP) chamber, a transformer coupled plasma chamber, conductor tools, dielectric tools, a plasma chamber including an electron cyclotron resonance (ECR) reactor, etc. For example, one or more RF generators are coupled to an inductor within the ICP reactor. Examples of a shape of the inductor include a solenoid, a dome-shaped coil, a flat-shaped coil, etc.

As noted above, depending on the process step or steps to be performed by the tool, the host computer communicates with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

With the above embodiments in mind, it should be understood that some of the embodiments employ various computer-implemented operations involving data stored in computer systems. These operations are those physically manipulating physical quantities. Any of the operations described herein that form part of the embodiments are useful machine operations.

Some of the embodiments also relate to a hardware unit or an apparatus for performing these operations. The apparatus is specially constructed for a special purpose computer. When defined as a special purpose computer, the computer performs other processing, program execution or routines that are not part of the special purpose, while still being capable of operating for the special purpose.

In some embodiments, the operations may be processed by a computer selectively activated or configured by one or more computer programs stored in a computer memory, cache, or obtained over the computer network. When data is obtained over the computer network, the data may be processed by other computers on the computer network, e.g., a cloud of computing resources.

One or more embodiments can also be fabricated as computer-readable code on a non-transitory computer-readable medium. The non-transitory computer-readable medium is any data storage hardware unit, e.g., a memory device, etc., that stores data, which is thereafter be read by a computer system. Examples of the non-transitory computer-readable medium include hard drives, network attached storage (NAS), read-only memory (ROM), random access memory (RAM), compact disc-ROMs (CD-ROMs), CD-recordables (CD-Rs), CD-rewritables (CD-RWs), magnetic tapes and other optical and non-optical data storage hardware units. In some embodiments, the non-transitory computer-readable medium includes a computer-readable tangible medium distributed over a network-coupled computer system so that the computer-readable code is stored and executed in a distributed fashion.

Although the method operations above were described in a specific order, it should be understood that in various embodiments, other housekeeping operations are performed in between operations, or the method operations are adjusted so that they occur at slightly different times, or are distributed in a system which allows the occurrence of the method operations at various intervals, or are performed in a different order than that described above.

It should further be noted that in an embodiment, one or more features from any embodiment described above are combined with one or more features of any other embodiment without departing from a scope described in various embodiments described in the present disclosure.

Although the foregoing embodiments have been described in some detail for purposes of clarity of understanding, it will be apparent that certain changes and modifications can be practiced within the scope of appended claims. Accordingly, the present embodiments are to be considered as illustrative and not restrictive, and the embodiments are not to be limited to the details given herein.

1. A system comprising:
a drive-resonator circuit configured to be coupled to an edge ring of a plasma chamber, wherein the edge ring is configured to surround a substrate support of the plasma chamber;
a controller coupled to the drive-resonator circuit, wherein the controller is configured to:
receive a first measurement signal from a bias sensor;
receive a second measurement signal from a ring sensor;
control, based on the first and second measurement signals, a parameter of the drive-resonator circuit to achieve uniformity in processing across a substrate.

2. The system of claim 1, wherein the drive-resonator circuit includes:
a matchless plasma source; and
a resonator circuit coupled to the matchless plasma source.

3. The system of claim 2, wherein the resonator circuit includes:
an inductor coupled in series with the matchless plasma source to form a series circuit;
a first capacitor coupled in parallel to the series circuit of the inductor and the matchless plasma source, wherein the first capacitor is a variable capacitor;
a second capacitor coupled to the inductor and the first capacitor, wherein the second capacitor is coupled to the edge ring.

4. The system of claim 3, wherein the parameter is a capacitance of the first capacitor, wherein to control the parameter of the drive-resonator circuit to achieve the uniformity, the controller is configured to modify the capacitance of the first capacitor until resonance is achieved between an inductive impedance of the resonator circuit and a capacitive impedance of a capacitance of the edge ring.

5. The system of claim 3, wherein the parameter is a capacitance of the first capacitor, wherein to control the parameter of the drive-resonator circuit to achieve the uniformity, the controller is configured to:
modify the capacitance of the first capacitor until a ratio of an amplitude of the second measurement signal and an amplitude of the first measurement signal is within a predetermined range.

6. The system of claim 1, wherein to control the parameter of the drive-resonator circuit to achieve the uniformity, the controller is configured to:
control a matchless plasma source of the drive-resonator circuit to operate at a frequency of operation same as the frequency of operation of a bias source; and
modify a phase of a radio frequency signal output from the matchless plasma source until a phase of the second measurement signal and a phase of the first measurement signal are within a predetermined phase range.

7. The system of claim 6, wherein to control the parameter of the drive-resonator circuit to achieve the uniformity, the controller is configured to:
modify an amplitude the radio frequency signal output from the matchless plasma source, wherein the frequency and phase are modified first before the amplitude is modified.

8. A method comprising:
receiving a first measurement signal from a bias sensor;
receiving a second measurement signal from a ring sensor;
controlling, based on the first and second measurement signals, a parameter of a drive-resonator circuit to achieve uniformity in processing across a substrate, wherein the drive-resonator circuit is configured to be coupled to an edge ring of a plasma chamber, wherein the edge ring is configured to surround a substrate support of the plasma chamber.

9. The method of claim 8, wherein the drive-resonator circuit includes:
a matchless plasma source; and
a resonator circuit coupled to the matchless plasma source.

10. The method of claim 9, wherein the resonator circuit includes:
an inductor coupled in series with the matchless plasma source to form a series circuit;
a first capacitor coupled in parallel to the series circuit of the inductor and the matchless plasma source, wherein the first capacitor is a variable capacitor;
a second capacitor coupled to the inductor and the first capacitor, wherein the second capacitor is coupled to the edge ring.

11. The method of claim 10, wherein the parameter is a capacitance of the first capacitor, wherein said controlling the parameter of the drive-resonator circuit to achieve the uniformity includes modifying the capacitance of the first capacitor until a ratio of an amplitude of the second measurement signal and an amplitude of the first measurement signal is within a predetermined range.

12. The method of claim 10, wherein said controlling the parameter of the drive-resonator circuit to achieve the uniformity includes:
controlling a matchless plasma source of the drive-resonator circuit to operate at a frequency of operation equal to the frequency of operation of a bias source; and
modifying a phase of a radio frequency signal output from the matchless plasma source until a phase of the second measurement signal and a phase of the first measurement signal are within a predetermined phase range.

13. The method of claim 12, wherein said controlling the parameter of the drive-resonator circuit to achieve the uniformity includes:
modifying an amplitude of the radio frequency signal output from the matchless plasma source, wherein said modifying the frequency and said modifying the phase occurs before said modifying the amplitude.

14. A system comprising:
a resonator circuit configured to be coupled to an edge ring of a plasma chamber, wherein the edge ring is configured to surround a substrate support of the plasma chamber;
a controller coupled to the resonator circuit, wherein the controller is configured to:
receive a first measurement signal from a bias sensor;
receive a second measurement signal from a ring sensor;
control, based on the first and second measurement signals, a parameter of the resonator circuit to achieve uniformity in processing across a substrate.

15. The system of claim 14, wherein the resonator circuit includes:
an inductor;
a first capacitor coupled in parallel to the inductor, wherein the first capacitor is a variable capacitor;
a second capacitor coupled to the inductor and the first capacitor, wherein the second capacitor is coupled to the edge ring.

16. The system of claim 15, wherein the parameter is a capacitance of the first capacitor, wherein to control the parameter of the resonator circuit to achieve the uniformity, the controller is configured to modify the capacitance of the first capacitor until resonance is achieved between an inductive impedance of the resonator circuit and a capacitive impedance of a capacitance of the edge ring.

17. The system of claim 15, wherein the parameter is a capacitance of the first capacitor, wherein to control the parameter of the resonator circuit to achieve the uniformity, the controller is configured to modify the capacitance of the first capacitor until a ratio of an amplitude of the second measurement signal and an amplitude of the first measurement signal is within a predetermined range.

18. The system of claim 14, wherein the first measurement signal is a voltage signal and the second measurement signal is a voltage signal.

19. The system of claim 14, wherein the edge ring is not supplied with radio frequency power from a radio frequency generator and the substrate support is supplied with radio frequency power from a bias source system.

20. The system of claim 14, wherein the edge ring is configured to be coupled to the ring sensor, and the substrate support is configured to be coupled to the bias sensor.
